(19) United States
(12) Patent Application Publication
(10) Pub. No.: US 2024/0121969 A1
(43) Pub. Date: Apr. 11, 2024

(54) SIMPLIFIED TANDEM STRUCTURE FOR SOLAR CELLS WITH TWO TERMINALS

(71) Applicants: COMMISSARIAT À L'ÉNERGIE ATOMIQUE ET AUX ÉNERGIES ALTERNATIVES, Paris (FR); 3SUN S.R.L., Catania (IT)

(72) Inventors: Apolline Puaud, Grenoble (FR); Muriel Matheron, Grenoble (FR); Maria-Delfina Munoz, Grenoble (FR)

(21) Appl. No.: 18/257,718

(22) PCT Filed: Dec. 13, 2021
(86) PCT No.: PCT/FR2021/052296

§ 371 Date: Jun. 15, 2023

(30) Foreign Application Priority Data
Dec. 18, 2020 (FR) 2013591

(51) Int. Cl. H10K 30/57

(52) U.S. Cl. CPC H10K 30/57

(57) ABSTRACT

A tandem photovoltaic structure including, from the rear face to the front face: a first solar cell—with a silicon heterojunction: a first layer of a first conductivity type made of amorphous silicon and a substrate of doped crystalline silicon disposed between two layers of intrinsic amorphous silicon, a recombination zone comprising a layer of nanocrystalline or monocrystalline silicon of the second conductivity type, a second solar cell comprising an active layer made of a perovskite material and a second layer of a second conductivity type. The recombination zone further includes a layer of the first conductivity type in contact with the active layer of the second cell or a layer of nanocrystalline or monocrystalline silicon of the first conductivity type in contact with the active layer of the second solar cell.

### TECHNICAL FIELD

The present invention relates to the field of photovoltaic devices, in particular 2-terminal perovskite tandem type photovoltaic cells on a silicon heterojunction.

The invention relates to a simplified structure having (photo)electrical properties comparable to those of a conventional tandem structure.

### PRIOR ART

Solar cells allow converting a portion of the spectral domain of solar radiation into energy. To increase the yield of this conversion, it is possible to manufacture structures with a tandem architecture comprising two subsets (i.e. a lower cell and an upper cell), absorbing in different spectral domains.

Many configurations are possible. For example, the lower cell 10 may be a cell made of perovskite, CIGS (Cu(In,Ga)Se₂), or it may consist of a silicon-based cell, for example, with a homojunction or with a silicon heterojunction (HET-Si or SHJ standing for “Silicon HeteroJunction solar cell”), of the PERC (“Passivated Emitter and Rear Contact”) or TopCon (“Tunnel Oxide Passivated Contact”) type or an N-type PERT cell with double diffusion of phosphorus.

For example, the upper cell 30 may be a perovskite, organic or multi-junction cell (MJSC) based on III-V materials (AlGaAs, GaInP, GaAs).

The two sub-cells are stacked on top of each other according to a NIP/NIP (FIG. 1A) or PIN/PIN (FIG. 1B) scheme

For illustration, in the case of 2-terminal perovskite-type tandem structures on a silicon heterojunction, the NIP-type structure conventionally comprises from the rear face to the front face (FIG. 1A):
a lower cell 10 comprising a layer of n-type doped amorphous silicon 11 ((n) a-Si:H), a substrate of n-type doped crystalline silicon 12 (c-Si(n)) disposed between two layers of intrinsic amorphous silicon 13, 14 ((i) a-Si:H),
a recombination zone 20,
an upper cell 30 comprising: an N-type layer 33 (SnO₂ for example), an active layer made of a perovskite material 31, a P-type layer 32 (PTAA for example).

Lower and upper electrodes 40, 50 as well as electrical contacts 60, 70 complete the structure.

In the case of a PIN-type structure, the P and N type layers are reversed and the structure conventionally comprises from the rear face to the front face (FIG. 1B):

a lower cell 10 comprising a layer of P-doped amorphous silicon 15 ((p) a-Si:H), a substrate of n-type doped crystalline silicon 12 (c-Si(n)), disposed between two layers of intrinsic amorphous silicon 13, 14 ((i) a-Si:H), a layer of N-type doped amorphous silicon 11 ((n) a-Si:H),
a recombination zone 20,
an upper cell 30 comprising: a P-type layer 32, an active layer made of a perovskite material 31 and an N-type layer 33.

Each sub-cell 10, 30 of the tandem structure includes layers which allow separating and selecting the charges according to their polarity.

The recombination zone 20 between the two sub-cells is called “recombination junction” because it enables the charges to recombine. It also enables the serial connection of the sub-cells and thus the addition of their voltages. It should lead to the recombination of the electrons generated in the upper cell and the holes generated in the lower cell for a NIP structure tandem (FIG. 1A) and the opposite for a PIN structure (FIG. 1B). For example, the recombination zone 20 is formed of a tunnel junction formed of two highly doped layers: one of the P type 21 ((p+) μc-Si:H) and the other one of the N type 22 ((n+) μc-Si:H). In the case of a NIP structure, the layer 21 of the recombination zone also serves as an emitter of the lower cell 10.

However, these tandem structures require many steps to be manufactured, which increases the manufacturing costs and the number of layers and interfaces likely to lower the performances (by adding serial resistance, contact resistances, undesirable recombinations, etc.).

It has been shown that a NIP-like tandem structure comprising a perovskite upper cell and a lower cell based on crystalline silicon and poly-Si could function by directly positioning the upper cell over the lower cell (Shen et al. “In situ recombination junction between p-Si and TiO₂ enables high-efficiency monolithic perovskite/Si tandem cells”, Science Advances, 2018; 4: eaau9711). More particularly, a layer of N-type TiO₂ is deposited by ALD directly over the P-doped silicon of the lower cell. Then, a layer of perovskite and a P-type layer made of PTAA are deposited. The operation of this structure is made possible thanks to the low contact resistivity between the ALD layer of TiO₂ and the P-doped silicon of the lower cell.

Similarly, a perovskite tandem structure on a silicon heterojunction has been manufactured by directly depositing the layer of N-type SnO₂ of the upper cell made of perovskite over the P-type layer of the lower cell (Zheng et al. “Large area efficient interface layer free monolithic perovskite/homo-junction-silicon tandem solar cell with over 20% efficiency”, Energy Environ. Sci., 2018, 11, 2432-2443).

However, to date, there is no simplified perovskite tandem structure on a silicon heterojunction based on amorphous silicon and crystalline silicon. Indeed, the amorphous silicon/crystalline silicon heterojunction is very sensitive to the temperature used during the process. In addition, the deposition of the perovskite active layer is generally carried out by liquid means and is therefore greatly dependent on the substrate over which it is deposited as well as the implemented manufacturing steps, which makes a modification of their architecture very difficult to carry out.

### DISCLOSURE OF THE INVENTION

The present invention aims to propose a two-terminal perovskite tandem structure on a silicon heterojunction based on amorphous silicon and crystalline silicon having good electrical properties and which is simpler and less expensive to manufacture.

For this purpose, the present invention provides a structure of 2-terminal perovskite tandem solar cells on a silicon heterojunction based on amorphous silicon and crystalline silicon comprising from the rear face to the front face:
a first solar cell with a silicon heterojunction based on amorphous silicon and crystalline silicon comprising, from the rear face to the front face: a first layer of a first conductivity type made of amorphous silicon, a substrate of crystalline silicon (of the first conductivity type or of a second conductivity type) disposed between two layers of intrinsic amorphous silicon, and possibly a first layer of a second conductivity type made of amorphous silicon,
a recombination zone comprising at least one layer based on nanocrystalline or microcrystalline silicon of the second conductivity type,
a second solar cell comprising an active layer made of a perovskite material and a second layer of a second conductivity type,
the recombination zone further comprising a second layer of the first conductivity type in contact with the active layer of the second cell solar cell or a layer based on nanocrystalline or microcrystalline silicon of the first conductivity type in contact with the active layer of the second solar cell.

The invention differs essentially from the prior art in that in these structures, one of the layers of the recombination zone has a dual function: both the role of charge selection (N or P type contact) and participates in the recombination junction function.

This functional structure enables the recombination of charges and the serial connection between the two sub-cells, without adding an additional layer and/or material between the two sub-cells of the tandem structure, as is the case in conventional tandem structures.

The recombination zone is a fully recombinant P-N junction (regardless of the recombination mechanisms). The recombination zone generates no reverse potential: no voltage drop in the tandem solar cell.

This simplified structure is simpler to manufacture compared to the structures of conventional tandem solar cells. The reduction in the number of structural layers and therefore of steps in the manufacturing process results in a reduction in manufacturing costs.

According to a first variant, the first conductivity type is an N-type conductivity (i.e. it is a NIP-type tandem structure).

According to this first variant, the structure may comprise from the rear face to the front face:
the first solar cell with a silicon heterojunction based on amorphous silicon and crystalline silicon comprising from the rear face to the front face: the first layer of the first conductivity type (N type) made of amorphous silicon and the substrate of crystalline silicon disposed between the two layers of intrinsic amorphous silicon,
the layer based on nanocrystalline or microcrystalline silicon of the second conductivity type (P type),
the second perovskite solar cell comprising towards the front face: the second layer of the first conductivity type (N type), preferably made of SnO₂, the active layer made of a perovskite material and the second layer of a second conductivity type (P type) preferably made of PTAA.

The recombination zone is then formed of the layer based on nanocrystalline or microcrystalline silicon of the second conductivity type (P type) and of the second layer of the first conductivity type (N type). These two layers are in direct contact.

With such an architecture, the upper cell is a conventional cell. This configuration allows obtaining high yields.

Alternatively, according to this same first variant, the structure may comprise from the rear face to the front face:
the first solar cell with a silicon heterojunction based on amorphous silicon and crystalline silicon comprising from the rear face to the front face: the first layer of the first conductivity type (N type) made of amorphous silicon and the substrate of crystalline silicon disposed between the two layers of intrinsic amorphous silicon,
the layer based on nanocrystalline or microcrystalline silicon of the second conductivity type (P type) and the layer based on nanocrystalline or microcrystalline silicon of the first conductivity type (N type),
the second perovskite solar cell comprising towards the front face: the active layer made of a perovskite material and the second layer of the second conductivity type (P type) preferably made of PTAA.

The recombination zone is then formed of the layer based on nanocrystalline or microcrystalline silicon of the second conductivity type (P type) and of the layer based on nanocrystalline or microcrystalline silicon of the first conductivity type (N type) which form a tunnel junction. The layer based on nanocrystalline or microcrystalline silicon of the first conductivity type (N type) also serves as a charge extractor in the second cell (perovskite). There is no need to add a layer of the first conductivity type (N type), such as an SnO₂ layer, in the second solar cell. The active layer of the second solar cell is in direct contact with the layer based on nanocrystalline or microcrystalline silicon of the first conductivity type (N type).

With this architecture, the layers based on nanocrystalline or microcrystalline silicon may be deposited in the same equipment as the layers made of amorphous silicon of the lower cell and over large surfaces in a homogeneous manner, which simplifies the manufacturing process and facilitates the obtainment of a homogeneous perovskite layer.

According to a second variant, the first conductivity type is a P-type conductivity (i.e. it consists of a PIN-type tandem structure).

According to this second variant, the structure may comprise from the rear face to the front face:
the first solar cell with a silicon heterojunction based on amorphous silicon and crystalline silicon comprising, from the rear face to the front face: the first layer of the first conductivity type (P type) made of amorphous silicon, the substrate of crystalline silicon disposed between the two layers of intrinsic amorphous silicon, possibly the first layer of the second conductivity type (N type) made of amorphous silicon,
the layer based on nanocrystalline or microcrystalline silicon of the second conductivity type (N type),
the second perovskite solar cell comprising towards the front face: the second layer of the first conductivity type (P type), preferably made of PTAA or of TFB or alternatively obtained from phosphonate(s), silanes or carboxylic acids, the active layer made of a perovskite material and the second layer of the second conductivity type (N type), preferably made of SnO₂ or a PCBM/SnO₂ or PCBM/BCP stack.

The recombination zone is then formed of the layer based on nanocrystalline or microcrystalline silicon of the second conductivity type (N type) and of the second layer of the first conductivity type (P type). These two layers are in direct contact.

With this PIN-type architecture, it is possible to obtain high currents. In addition, the lower cell is a conventional heterojunction cell and needs no more description.

Alternatively, according to this same second variant, the structure may comprise from the rear face to the front face:
the first solar cell with a silicon heterojunction based on amorphous silicon and crystalline silicon comprising from the rear face to the front face: the first layer of the first conductivity type (P type) made of amorphous silicon, the substrate of crystalline silicon disposed between the two layers of intrinsic amorphous silicon, the first layer of the second conductivity type (N type) made of amorphous silicon,
the layer based on nanocrystalline or microcrystalline silicon of the second conductivity type (N type) and the layer based on nanocrystalline or microcrystalline silicon of the first conductivity type (P type),
the second perovskite solar cell comprising towards the front face: the active layer made of a perovskite material and the second layer of the second conductivity type (N type) preferably made of SnO₂ or a PCBM/SnO₂ or PCBM/BCP stack.

The recombination zone is then formed of the layer based on nanocrystalline or microcrystalline silicon of the second conductivity type (N type) and a layer based on nanocrystalline or microcrystalline silicon of the first conductivity type (P type) which form a tunnel junction. The layer based on nanocrystalline or microcrystalline silicon of the first conductivity type (P type) also serves as a charge extractor in the perovskite cell. There is no need to add a layer of the first conductivity type (P type), such as a layer of PTAA, in the second solar cell. The active layer of the second solar cell is in direct contact with the layer based on nanocrystalline or microcrystalline silicon of the first conductivity type (P type).

With this architecture, the layers based on nanocrystalline or microcrystalline silicon may be deposited in the same equipment as the layers made of amorphous silicon of the lower cell and over large surfaces in a homogeneous manner, which simplifies the manufacturing process and facilitates the obtainment of a homogeneous perovskite layer. High currents may be obtained with this architecture.

Advantageously, the layer based on nanocrystalline or microcrystalline silicon of the first conductivity type and/or the layer based on nanocrystalline or microcrystalline silicon of the second conductivity type is made of μc-Si:H (p+), μc-Si:H (n+), N or P type nc-SiCₓ or N or P type nc-SiO_{y} with x ranging from 0 to 1 and y ranging from 0 to 2.

By nanocrystalline or microcrystalline, it should be understood a layer including both an amorphous phase and a crystalline phase, the crystalline phase having a grain size smaller than 30 nm. It is generally comprised between 1 and 10 nm for nanocrystalline silicon and generally between 10 and 30 nm and preferably between 10 and 20 nm for microcrystalline. Sometimes, in the literature, for grain sizes smaller than 10 nm, the microcrystalline silicon designation is also found.

Advantageously, the layer based on nanocrystalline or microcrystalline silicon of the first conductivity type and/or the layer based on nanocrystalline or microcrystalline silicon of the second conductivity type has a thickness ranging from 15 nm to 60 nm and preferably from 20 nm to 40 nm.

Advantageously, the layer based on nanocrystalline or microcrystalline silicon of the first conductivity type and/or the layer based on nanocrystalline or microcrystalline silicon of the second conductivity type has a conductivity higher than 10⁻³ S·cm⁻¹.

Advantageously, the layer based on nanocrystalline or microcrystalline silicon of the first conductivity type and/or the layer based on nanocrystalline or microcrystalline silicon of the second conductivity type has a doping level of 10¹⁸/cm³ to 10²²/cm³, and preferably between 10¹⁹/cm³ and 10²⁰/cm³ for the P type and between 10²⁰/cm³ and 10²¹/cm³ for the N type.

Other features and advantages of the invention will appear from the following complementary description.

It goes without saying that this complementary description is given only for illustration of the object of the invention and should in no way be interpreted as a limitation of this object.

### BRIEF DESCRIPTION OF THE DRAWINGS

The present invention will be better understood upon reading the description of embodiments given merely for informative and non-limiting purposes with reference to the appended drawings wherein:

FIG. 1A previously described in the prior art represents, schematically and in section, a two-terminal NIP-NIP tandem structure.

FIG. 1B previously described in the prior art represents, schematically and in section, a two-terminal PIN-PIN tandem structure.

FIG. 2A represents, schematically and in section, a simplified two-terminal NIP-NIP tandem structure, according to a particular embodiment of the invention.

FIG. 2B represents, schematically and in section, a simplified two-terminal PIN-PIN tandem structure, according to another particular embodiment of the invention.

FIG. 3A represents, schematically and in section, a simplified two-terminal NIP-NIP tandem structure, according to another particular embodiment of the invention.

FIG. 3B represents, schematically and in section, a simplified two-terminal PIN-PIN tandem structure, according to another particular embodiment of the invention.

FIGS. 4A and 4B are graphs representing the EQE and the ‘1-Rtot’ value as a function of the wavelength (with Rtot corresponding to the total reflection of the stack of the cell (without the metallisation at the front face)), obtained for tandem structures polished at the front face and at the rear face, of the NIP type (corresponding to FIGS. 1A, 2A and 3A) and of the PIN type (corresponding to FIGS. 1B, 2B and 3B) respectively.

FIGS. 5A and 5B are graphs representing the EQE and the ‘1-Rtot’ value as a function of the wavelength, obtained for tandem structures whose substrate is polished at the front face and with a classic pyramidal texturing at the rear face, of the NIP type (corresponding to FIGS. 1B, 2B and 3B) and of the PIN type (corresponding to FIGS. 1A, 2A and 3A) respectively.

FIGS. 6A and 6B are graphs representing the EQE and the ‘1-Rtot’ value as a function of the wavelength, obtained for textured tandem structures at the front face and at the rear face, of the NIP type (corresponding to FIGS. 1A, 2A and 3A) and of the PIN type (corresponding to FIGS. 1B, 2B and 3B) respectively.

The different portions represented in the figures are not necessarily plotted according to a uniform scale, to make the figures more readable.

Furthermore, in the description hereinafter, terms that depend on the orientation, such as “top”/“upper”, “bottom”/“lower”, etc. of a structure apply while considering that the tandem device and the test structure are oriented as illustrated in the figures.

### DETAILED DISCLOSURE OF PARTICULAR EMBODIMENTS

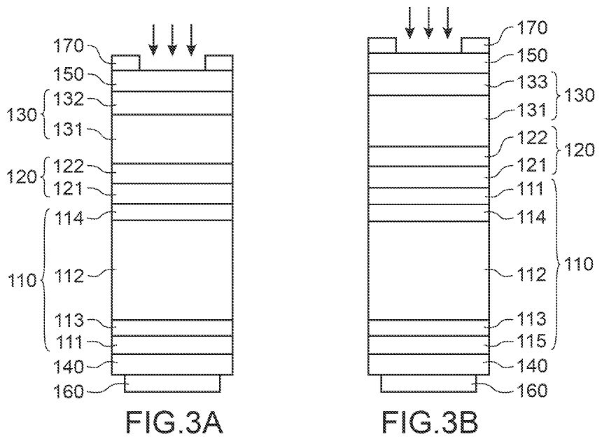

FIGS. 2A, 2B, 3A and 3B represent four simplified perovskite tandem structures 100 over a silicon heterojunction (amorphous silicon/crystalline silicon). Each of these tandem structures 100 comprises:
a first cell 110 (or lower cell for “bottom cell”) with a silicon heterojunction (HET-Si or SHJ standing for “Silicon HeteroJunction solar cell”) positioned at the rear face of the device,
a recombination zone: a completely recombinant P-N junction (regardless of the recombination mechanisms), made without addition of additional layers and/or materials; the recombination zone does not lead to any reverse potential (i.e. no voltage drop in the tandem solar cell),
a second perovskite cell 130 (or upper cell for “top cell”) positioned at the front face of the device.

The face intended to receive the light radiation (represented by arrows in the figures) is called front face.

We will now detail these four different structures in more detail.

First of all, reference is made to the tandem structure 100 represented in FIG. 2A. This NIP-type (or standard emitter) tandem structure 100 comprises:
the first solar cell 110 with a silicon heterojunction (based on amorphous silicon and crystalline silicon) comprising from the rear face to the front face: a first layer made of N-doped amorphous silicon (for example a layer of n-doped hydrogenated amorphous silicon also denoted (n) a-Si:H) 111 and a substrate of doped crystalline silicon 112 (for example a substrate of n-doped crystalline silicon also denoted c-Si (n)) disposed between two layers of intrinsic amorphous silicon 113, 114 (also called layers of (i) a-Si:H or intrinsic hydrogenated amorphous silicon),
a layer 121 based on P-type nanocrystalline or microcrystalline silicon (for example a layer of p+ doped hydrogenated microcrystalline silicon also denoted (p+) μc-Si:H layer), which also serves as an emitter in the heterojunction cell,
a second perovskite solar cell 130 comprising towards the front face: an N-type layer 133 (for example a layer made of SnO₂), an active layer 131 made of a perovskite material and a P-type layer 132 (for example a layer made of PTAA).

Reference is not made to the tandem structure 100 represented in FIG. 2B. This PIN-type (or with an inverted emitter) tandem structure 100 comprises:
the first solar cell 110 with a silicon heterojunction based on amorphous silicon and crystalline silicon comprising from the rear face to the front face: a P-type amorphous silicon layer 115 (for example a p-doped hydrogenated amorphous silicon layer, also denoted (p) a-Si:H), a substrate of doped crystalline silicon 112 (for example a c-Si(n) substrate) disposed between two layers of intrinsic amorphous silicon 113, 114 (for example (i) a-Si:H), and possibly a first layer of N-type amorphous silicon 111 (for example (n) a-Si:H), which is also the incubation layer of the nano or microcrystalline layer 122,
a layer based on N-type nanocrystalline or microcrystalline silicon 122 (for example a layer of n+ doped hydrogenated microcrystalline silicon also denoted (n+) μc-Si:H layer),
a second perovskite solar cell 130 comprising towards the front face: a P-type layer 132 (for example a layer made of PTAA or TBF), an active layer 131 made of a perovskite material and an N-type layer 133 (for example a layer made of SnO₂ or a PCBM/SnO₂ or PCBM/BCP bilayer).

In these two structures represented in FIGS. 2A and 2B, the layer based on nanocrystalline or microcrystalline silicon of the first conductivity type (P in the case of a NIP structure and N in the case of a PIN structure) is in direct contact with the layer of the second conductivity type (N in the case of a NIP structure and P in the case of a PIN structure) of the second cell 130. The recombination junction is located between the layer based on nanocrystalline or microcrystalline silicon of the first conductivity type and the charge carrier/extractor material of the second conductivity type of the second solar cell 130 (i.e. between the layers 121 and 133 for the NIP structure and between the layers 122 and 132 for the PIN structure).

Reference is now made to the tandem structure 100 represented in FIG. 3A. This NIP-type (or standard emitter) tandem structure 100 comprises:
a first solar cell 110 with a silicon heterojunction based on amorphous silicon and crystalline silicon comprising, from the rear face to the front face: a layer of N-type amorphous silicon 111 (for example (n) a-Si:H) and a substrate of crystalline silicon 112 (for example a c-Si (n) substrate) disposed between two layers of intrinsic amorphous silicon 113, 114 (for example (i) a-Si:H),
a layer 121 based on P-type nanocrystalline or microcrystalline silicon which also serves as an emitter of the heterojunction cell (for example (p+) μc-Si:H) and a layer based on N-type nanocrystalline or microcrystalline silicon 122 (for example (n+) μc-Si:H),
a second perovskite solar cell 130 comprising towards the front face: an active layer (131) made of a perovskite material and a P-type layer 132 (for example a layer made of PTAA).

Reference is not made to the tandem structure 100 represented in FIG. 3B. This PIN-type (or with an inverted emitter) tandem structure 100 comprises:
a first solar cell 110 with a silicon heterojunction based on amorphous silicon and crystalline silicon comprising from the rear face to the front face: a layer of P-type amorphous silicon 115 (for example (p) a-Si:H) and a substrate of crystalline silicon 112 (for example a c-Si (n) substrate) disposed between two layers of intrinsic amorphous silicon 113, 114 (for example (i) a-Si:H), possibly a layer of N-type amorphous silicon 111 (for example (n) a-Si:H), which is also the incubation layer of the nano or microcrystalline layer 121,
a layer based on N-type nanocrystalline or microcrystalline silicon 121 (for example (n+) μc-Si:H) and a layer based on P-type nanocrystalline or microcrystalline silicon 122 (for example (p+) μc-Si: H),
a second perovskite solar cell 130 comprising towards the front face: an active layer 131 made of a perovskite material and an N-type layer 133 (for example a layer made of SnO₂ or a PCBM/SnO₂ bilayer).

In these two structures represented in FIGS. 3A and 3B, the layer based on P-type nanocrystalline or microcrystalline silicon 121 or 122 and the layer based on N-type nanocrystalline or microcrystalline silicon 122 or 121 form a tunnel junction 120. One of these layers is in direct contact with the active layer 131 of the second solar cell 130 and then also serves as a charge extractor in the second cell 130.

For these different tandem structures 100 disclosed before, the layers of P type (p+) and/or N type (n+) nanocrystalline or microcrystalline silicon may have a thickness ranging from 20 to 40 nm.

In the case of a P-doped layer, the Fermi level is between 4.5 and 5.9 eV.

In the case of an N-doped layer, the Fermi level is between 3.9 and 4.4 eV.

The nanocrystalline or microcrystalline silicon layers are heavily doped. The doping of the layers of (p+ or n+) nanocrystalline or microcrystalline silicon ranges, for example, from 10¹⁸ to 10²²/cm³.

Preferably, the layers based on nanocrystalline or microcrystalline silicon are made of μc-Si:H (p+), μc-Si:H (n+), N or P type nc-SiCₓ or N or P type nc-SiO_{y} with x ranging from 0 to 1 and y from 0 to 2.

Advantageously, such layers have a high vertical conductivity, a low vertical resistance (typically lower than 0.5 Ohm·cm²) and/or a lateral conductivity higher than 10⁻³ S·cm⁻¹.

For example, the p/n type doping levels of the layers 111 and 115 are between 10¹⁸ and 10¹⁹/cm³.

The silicon substrate 12 of the lower cell may be polished or textured (for example, it may consist of texturing in the form of 2 μm pyramids). The amorphous layers of the lower cell having a thickness of a few nanometres, they will take on the shape of the texturing of the substrate.

The N-type layer 133 of the perovskite cell 130 also called “electron transport layer” (or EIL standing for “Electron Injection Layer” or ETL standing for “Electron Transport Layer”) is, for example, a metal oxide such as zinc oxide (ZnO), aluminium-doped zinc oxide also called AZO (ZnO:Al), titanium oxide (TiO₂) or tin oxide (SnO₂). It may also consist of a stack of methyl [6,6]-phenyl-C₆₁-butanoate and SnO₂ (PCBM/SnO₂) or methyl [6,6]-phenyl-C₆₁-butanoate and of bathocuproine (PCBM/BCP).

The P-type layer 132 of the perovskite cell 130 is also called “hole transport layer” (or HTL standing for “Hole Transport Layer”). For example, the P-type layer 132 is an organic compound like Poly(3,4-ethylenedioxythiophene) Polystyrene sulfonate (PEDOT:PSS), [poly(bis 4-phenyl}{2,4,6-trimethylphenyl}amine)] (PTAA), [Poly(N,N′-bis(4-butylphenyl)-N,N′-bis(phenyl)-benzidine] (Poly-TPD), 2,2′,7,7′-Tetrakis[N,N-di(4-methoxyphenyl)amino]-9,9′-spirobifluorene (spiro-OMeTAD), N4,N4′-bis(4-(6-((3-ethyloxetan-3-yl)methoxy)hexyl)phenyl)-N4,N4′-diphenyl-[1,1′-biphenyl]-4,4′-diamine (OTPD), poly[(9,9-dioctylfluorenyl-2,7-diyl)-co-(4,4′-(N-(4-sec-butylphenyl)diphenylamine)] (TFB) or pyrene, or else a metal oxide such as a molybdenum oxide, a vanadium oxide or a tungsten oxide.

The active layer 131 of the perovskite cell 130 comprises at least one perovskite material. The perovskite material has the general formula ABX 3 with A representing one or more monovalent organic cation(s), such as an ammonium, like methylammonium or formamidinium, or a monovalent metal cation, like cesium or rubidium; B representing a divalent metal cation like Pb, Sn, Ag or a mixture thereof; and X representing one or more halide anion(s).

More particularly, the perovskite material may have the particular formula H₂NCHNH₂PbX₃ or CH₃NH₃PbX₃ with X a halogen. For example, it may consist of methylammonium lead iodide CH₃NH₃PbI₃. Preferably, the perovskite material has the formula CsₓFA₁₋ₓPb(I_{1-y}Br_{y})₃.

The tandem device 100 may also comprise:
a first electrode 140 (lower electrode) disposed at the rear face; the lower electrode 140 may advantageously be opaque or of limited transparency, for example a transparent conductive oxide such as in particular ITO, 10H (hydrogenated indium oxide), or AZO
a second electrode 150 (upper electrode) disposed over the front face of the device; the second electrode is electrically-conductive and optically-transparent, so as to let the photons pass up to the active layer 131 of the upper cell 130. This electrode 150 may be made of a transparent conductive oxide, typically indium-tin oxide (ITO) or aluminium-doped zinc oxide (ZnO:Al), IZO, IZrO, IWO, etc., or it may be formed of a transparent conductive polymer comprising silver nanowires for example,
contact pads 160 at the rear face and contact pads 170 at the front face; the contact pads may for example be made of gold, aluminium or silver. (deposited for example by evaporation, or printed by screen-printing, inkjet printing, etc.).

### Illustrative and Non-Limiting Examples of One Embodiment

In this example, a conventional tandem structure and two simplified tandem structures have been selected.

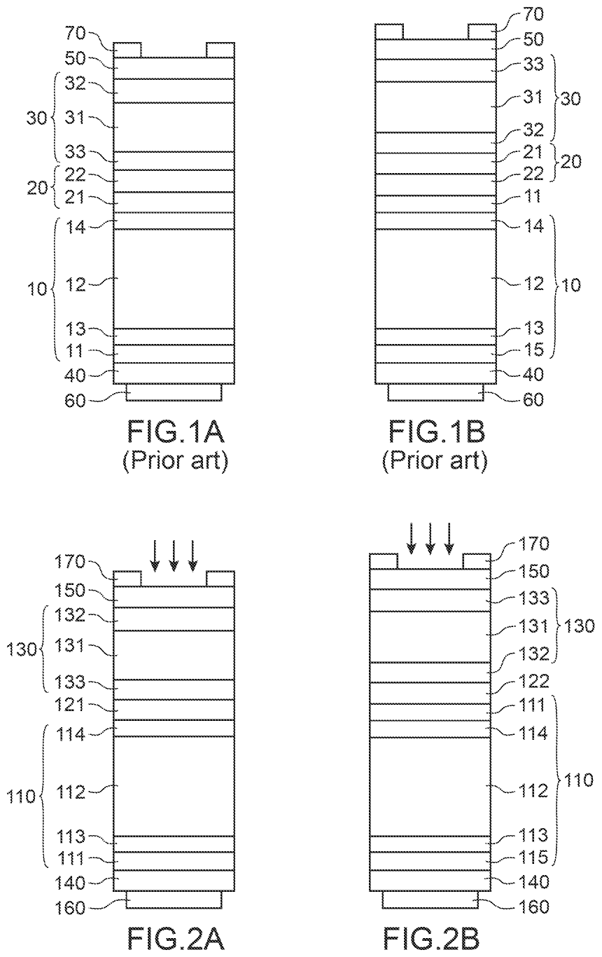

The conventional tandem structure is represented in FIGS. 1A and 1B.

The simplified tandem structures 100 are represented in FIGS. 2A, 2B, 3A and 3B.

The following Tables 1 and 2 list the thicknesses of the simulated layers for NIP and PIN-type architectures respectively. The perovskite used in the simulations is of the CsₓFA₁₋ₓPb(I_{1-y}Br_{y})₃ type (with x<0.20; 0<y<1). Two different thicknesses have been used to obtain less current deviation between the two sub-cells when the surface condition is modified. The disclosed results will be with a perovskite that is 250 nm thick when the front face is polished and 415 nm thick when it is textured.

The following Table 1 lists the thicknesses (nm) of the simulated layers for the NIP-type architectures:

| | FIG. 1A NIP | FIG. 2A NIP | FIG. 3A NIP |
|---|---|---|---|
| ITO front face | 180 | 180 | 180 |
| PTAA | 30 | 30 | 30 |
| Perovskite active layer | 250 and 415 | 250 and 415 | 250 and 415 |
| SnO₂ | 30 | 30 | / |
| (n+) μc-Si:H | 20 | / | 20 |
| (p+) μc-Si:H | 25 | 25 | 25 |
| a-Si:H (p) | / | / | / |
| a-Si:H (i) | 10 | 10 | 10 |
| c-Si | 280000 | 280000 | 280000 |
| a-Si:H (i) | 5 | 5 | 5 |
| a-Si:H (n) | 8 | 8 | 8 |
| ITO rear face | 70 | 70 | 70 |
| Ag | 200 | 200 | 200 |

The following Table 2 lists the thicknesses (nm) of the simulated layers for the PIN-type architectures:

| | FIG. 1B PIN | FIG. 2B PIN | FIG. 3B PIN |
|---|---|---|---|
| ITO front face | 180 | 180 | 180 |
| SnO₂ | 30 | 30 | 30 |
| Perovskite active layer | 250 and 415 | 250 and 415 | 250 and 415 |
| PTAA | 30 | 30 | / |
| (p+) μc-Si:H | 16 | / | 16 |
| (n+) μc-Si:H | 24 | 24 | 24 |
| a-Si:H (n) | 8 | 8 | 8 |
| a-Si:H (i) | 5 | 5 | 5 |
| c-Si | 280000 | 280000 | 280000 |
| a-Si:H (i) | 5 | 5 | 5 |
| a-Si:H (p) | 19 | 19 | 19 |
| ITO rear face | 70 | 70 | 70 |
| Ag | 200 | 200 | 200 |

Optical simulations of these structures have been carried out using the CROWM software, while taking into account the optical indices of the layers, their thickness and the surface condition (completely flat, textured, etc.).

These simulations are performed between 310 and 1,200 nm with the AM1.5 solar spectrum. The optical indices have been extracted by ellipsometry from the experimental layers.

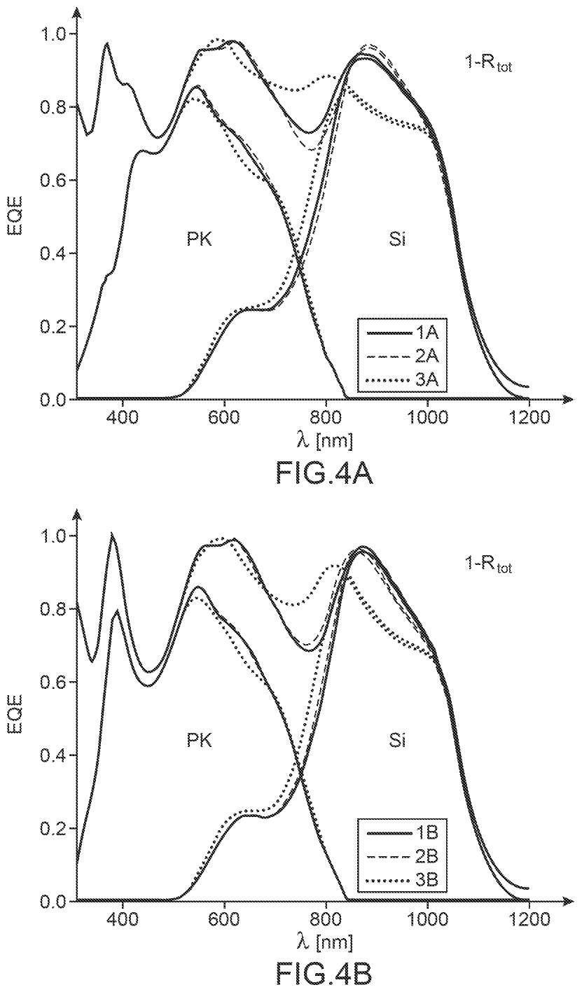

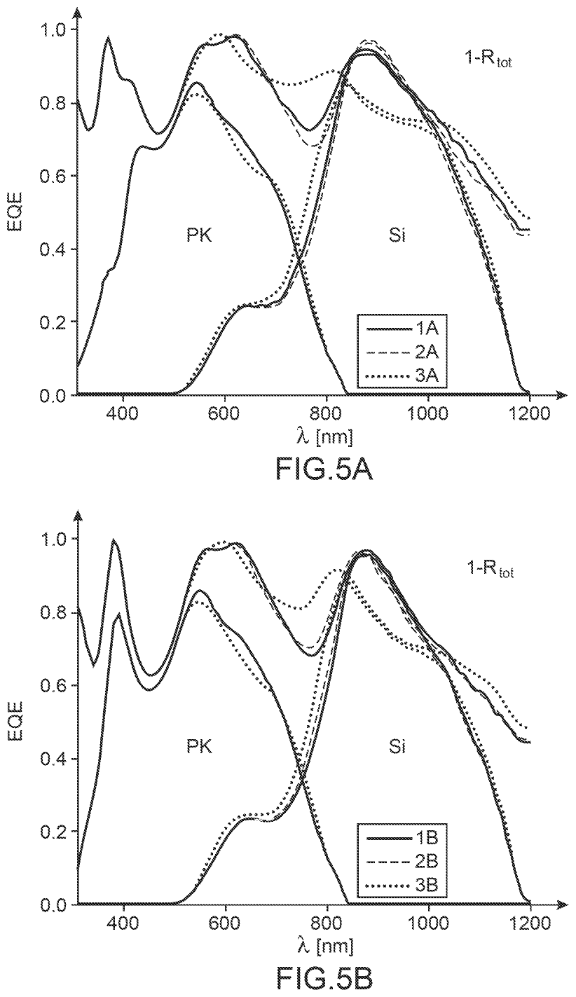

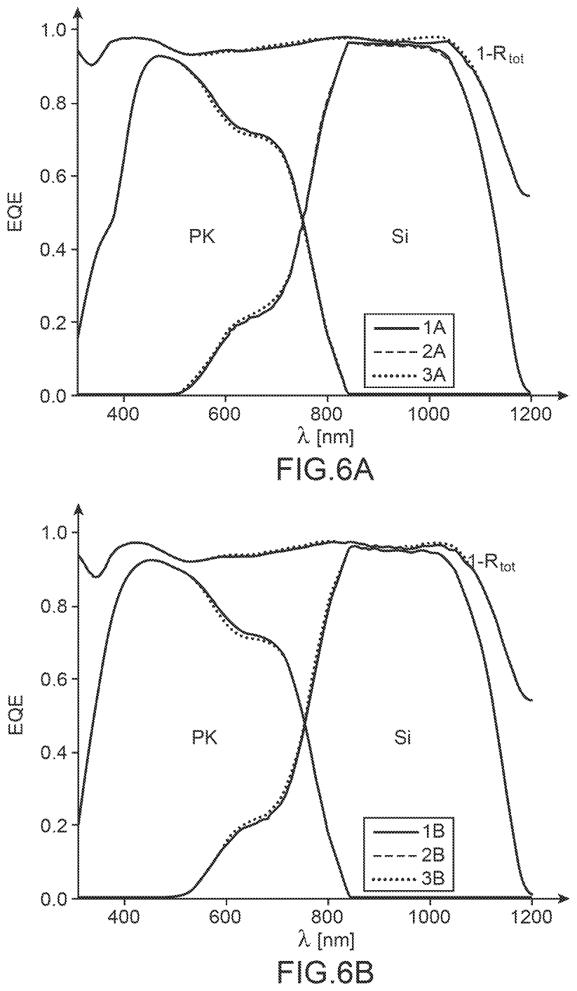

The obtained curves representing the external quantum efficiency (EQE) and the ‘1-Rtot’ value are represented in FIGS. 4A, 4B, 5A, 5B, 6A and 6B.

This optical simulation study demonstrates that simplified NIP and PIN tandem structures with a junction made of microcrystalline silicon are viable regardless of texturing. Indeed, these simplified structures have only very few differences from an optical perspective with the complete structures and have the same optical potential.

Table 3 lists the values of J_{sc} and Rₜₒₜ obtained by optical simulations, and the estimated PCEs for FF=75% and V, =1.8 V for conventional tandem structures (as represented in FIGS. 1A and 1B) and simplified tandem structures as represented in FIGS. 2A, 2B and 3A, 3B. The front and rear faces of the tandem structures may be polished or textured independently of each other.

| | | | | | | | |
|---|---|---|---|---|---|---|---|
| Front face | Rear face | NIP/PIN | FIG. | J_{sc} PK (mA/cm²) | J_{sc} Si (mA/cm²) | PCE (%) | Rₜₒₜ (mA/cm²) |

Conventional tandem structure

| | | | | | | | |
|---|---|---|---|---|---|---|---|
| polished | textured | NIP | 1A | 16.59 | 18.04 | 22.4 | 8.53 |
| polished | textured | PIN | 1B | 16.82 | 17.4 | 22.71 | 9.61 |
| polished | polished | NIP | 1A | 16.59 | 17 | 22.4 | 10.92 |
| polished | polished | PIN | 1B | 16.82 | 16.47 | 22.23 | 11.85 |
| textured | textured | NIP | 1A | 19.44 | 20.87 | 26.24 | 3.06 |
| textured | textured | PIN | 1B | 19.94 | 20.64 | 26.92 | 3.33 |

Simplified tandem structure with a recombination junction located between the microcrystalline silicon layer
and a charge transporter/extractor material of the perovskite sub-cell

| | | | | | | | |
|---|---|---|---|---|---|---|---|
| polished | textured | NIP | 2A | 16.7 | 17.7 | 22.55 | 8.97 |
| polished | textured | PIN | 2B | 16.84 | 17.42 | 22.73 | 9.62 |
| polished | polished | NIP | 2A | 16.7 | 16.75 | 22.55 | 11.21 |
| polished | polished | PIN | 2B | 16.84 | 16.47 | 22.23 | 11.87 |
| textured | textured | NIP | 2A | 19.55 | 20.77 | 26.39 | 3.16 |
| textured | textured | PIN | 2B | 19.91 | 20.7 | 26.88 | 3.33 |

Simplified tandem structure with a recombination junction comprising two microcrystalline silicon layers,
one of the microcrystalline silicon layers serving as a charge extractor of the perovskite sub-cell

| | | | | | | | |
|---|---|---|---|---|---|---|---|
| polished | textured | NIP | 3A | 16.39 | 18.09 | 22.13 | 8.53 |
| polished | textured | PIN | 3B | 16.59 | 17.63 | 22.4 | 9.47 |
| polished | polished | NIP | 3A | 16.39 | 16.98 | 22.13 | 11.1 |
| polished | polished | PIN | 3B | 16.59 | 16.6 | 22.4 | 11.91 |
| textured | textured | NIP | 3A | 19.25 | 21.14 | 25.99 | 2.97 |
| textured | textured | PIN | 3B | 19.74 | 20.91 | 26.65 | 3.24 |

The simplified tandem structures represented in FIGS. 3A and 3B prove to be different from the others in terms of distribution of the absorption in the tandem cell, however the resulting short-circuit currents are very similar.

What is claimed is:

1. A 2-terminal tandem photovoltaic structure comprising from the rear face to the front face:
a first solar cell with a silicon heterojunction comprising, from the rear face to the front face: a first layer of a first conductivity type made of amorphous silicon and a substrate of crystalline silicon of the first conductivity type or of a second conductivity type, disposed between two layers of intrinsic amorphous silicon, and optionally a first layer of a second conductivity type made of amorphous silicon,
a recombination zone comprising a layer based on nanocrystalline or microcrystalline silicon of the second conductivity type, and a second layer of the first conductivity type, possibly based on nanocrystalline or microcrystalline silicon of the first conductivity type,
an active layer made of a perovskite material and a second layer of a second conductivity type,
wherein the second layer of the first conductivity type of the recombination zone is in contact with the active layer made of a perovskite material and with the layer based on nanocrystalline or microcrystalline silicon of the second conductivity type of the recombination zone.

2. The tandem structure according to claim 1, wherein the layer based on nanocrystalline or microcrystalline silicon of the first conductivity type and/or the layer based on nanocrystalline or microcrystalline silicon of the second conductivity type is made of μc-Si:H (p+), μc-Si:H (n+), N or P type nc-SiCₓ or N or P type nc-SiO_{y} with x ranging from 0 to 1 and y ranging from 0 to 2.

3. The tandem structure according to claim 1, wherein the layer based on nanocrystalline or microcrystalline silicon of the first conductivity type and/or the layer based on silicon nanocrystalline or microcrystalline of the second conductivity type has a thickness ranging from 15 nm to 60 nm and preferably from 20 to 40 nm.

4. The tandem structure according to claim 1, wherein the layer based on nanocrystalline or microcrystalline silicon of the first conductivity type and/or the layer based on nanocrystalline or microcrystalline silicon of the second conductivity type has a conductivity higher than 10⁻³ S·cm⁻¹.

5. The tandem structure according to claim 1, wherein the layer based on nanocrystalline or microcrystalline silicon of the first conductivity type and/or the layer based on nanocrystalline or microcrystalline silicon of the second conductivity type has a doping level of 10¹⁸/cm³ to 10²²/cm³.

6. The tandem structure according to claim 1, wherein the first conductivity type is of the N type.

7. The tandem structure according to claim 6, wherein the structure comprises from the rear face to the front face:
the first solar cell with a silicon heterojunction based on amorphous silicon and crystalline silicon comprising, from the rear face to the front face: the first N-type layer made of amorphous silicon and the substrate of crystalline silicon disposed between the two layers of intrinsic amorphous silicon,
the layer based on P-type nanocrystalline or microcrystalline silicon,
a second perovskite solar cell comprising towards the front face: the second N-type layer, preferably made of SnO₂, the active layer made of a perovskite material and the second P-type layer-4324 preferably made of PTAA.

8. The tandem structure according to claim 6, the structure comprising from the rear face to the front face:
the first solar cell with a silicon heterojunction based on amorphous silicon and crystalline silicon comprising, from the rear face to the front face: the first N-type layer made of amorphous silicon and the substrate of crystalline silicon disposed between the two layers of intrinsic amorphous silicon,
the layer based on P-type nanocrystalline or microcrystalline silicon and the layer based on N-type nanocrystalline or microcrystalline silicon,
the second perovskite solar cell comprising towards the front face: the active layer made of a perovskite material and the second P-type layer preferably made of PTAA.

9. The tandem structure according to claim 1, wherein the first conductivity type is of the P type.

10. The tandem structure according to claim 9, the structure comprising from the rear face to the front face:
the first solar cell with a silicon heterojunction based on amorphous silicon and crystalline silicon comprising, from the rear face to the front face: the first P-type layer made of amorphous silicon, the substrate of crystalline silicon disposed between the two layers of intrinsic amorphous silicon, and the first N-type layer made of amorphous silicon,
the layer based on N-type nanocrystalline or microcrystalline silicon,
a second perovskite solar cell comprising towards the front face: the second P-type layer, preferably made of PTAA or TFB, the active layer made of a perovskite material and the second N-type layer preferably made of SnO₂ or a PCBM/SnO₂ bilayer.

11. The tandem structure according to claim 9, the structure comprising from the rear face to the front face:
the first solar cell with a silicon heterojunction based on amorphous silicon and crystalline silicon comprising, from the rear face to the front face: the first P-type layer made of amorphous silicon, the substrate of crystalline silicon disposed between the two layers of intrinsic amorphous silicon, and the first N-type layer made of amorphous silicon,
the layer based on N-type nanocrystalline or microcrystalline silicon and the layer based on P-type nanocrystalline or microcrystalline silicon,
a second perovskite solar cell comprising towards the front face: the active layer made of a perovskite material and the second N-type layer preferably made of SnO₂ or a PCBM/SnO₂ bilayer.
